(19) United States
(12) Patent Application Publication
(10) Pub. No.: US 2026/0205071 A1
(43) Pub. Date: Jul. 16, 2026

(54) Radio-Frequency Power Amplifier Circuitry

(71) Applicant: Apple Inc., Cupertino, CA (US)

(72) Inventors: Fei Wang, Sunnyvale, CA (US); Xiang Guan, Saratoga, CA (US)

(21) Appl. No.: 19/016,217

(22) Filed: Jan. 10, 2025

(51) Int. Cl. H03F 3/24; H03F 1/56

(52) U.S. Cl. CPC H03F 3/245; H03F 1/56; H03F 2200/222; H03F 2200/387; H03F 2200/451

(57) ABSTRACT

An electronic device may include wireless circuitry that includes a power amplifier with one or more common source stages. Each stage may include power transistors and, if desired, capacitance neutralization transistors. Each transistor may include a set of unit cells, each containing an elongated drain contact, first and second elongated source contacts, and first and second gate contacts. The source contacts may extend parallel to the drain contact along first and second sides of the drain contact. The gate contacts may extend orthogonal to the drain contact along third and fourth sides of the drain contact. The double gate connection for each unit cell may serve to reduce gate resistance of the corresponding transistor. The first and second power transistors may be laterally interposed on a substrate between the first and second capacitance neutralization transistors. This may serve to reduce area consumption while eliminating differential mode parasitics.

### FIELD

This disclosure relates generally to electronic devices, including electronic devices with wireless circuitry.

### BACKGROUND

Electronic devices can be provided with wireless communications capabilities. An electronic device with wireless communications capabilities has wireless circuitry with one or more antennas. Wireless transceiver circuitry in the wireless circuitry uses the antennas to transmit and receive radio-frequency signals.

Radio-frequency signals transmitted by an antenna can be fed through a power amplifier, which is configured to amplify low power analog signals to higher power signals more suitable for transmission through the air over long distances. It can be challenging to design satisfactory radio-frequency amplifier circuitry such as power amplifiers for an electronic device.

### SUMMARY

An electronic device may include wireless circuitry. The wireless circuitry may include a transmit path. The transmit path may include a power amplifier. The power amplifier may include a set of one or more amplifier stages. Each amplifier stage may include first and second power transistors. If desired, each amplifier stage may also include first and second capacitance neutralization transistors.

Each of the transistors may include a respective set of transistor unit cells in a semiconductor substrate. Each set may collectively share a source node, a gate node, and a drain node of the corresponding transistor. Each unit cell may include an elongated drain contact of the drain node, first and second elongated source contacts of the source node, and first and second gate contacts of the gate node. The elongated source contacts may extend parallel to the elongated drain contact along first and second sides of the drain contact. The gate contacts may extend orthogonal to the drain contact along third and fourth sides of the drain contact. Gate lines may couple the gate contacts together. Source lines may couple the source contacts together. The double gate connection for each unit cell may serve to reduce gate resistance of the corresponding transistor. In addition, the first and second power transistors may be laterally interposed on the semiconductor substrate between the first and second capacitance neutralization transistors. This may serve to reduce the area of the amplifier and may minimize interconnect length between source nodes of the power transistors, preventing differential mode parasitics from deteriorating amplifier performance.

An aspect of the disclosure provides a radio-frequency amplifier. The radio-frequency amplifier can include an input matching network. The radio-frequency amplifier can include an output matching network. The radio-frequency amplifier can include a semiconductor substrate. The radio-frequency amplifier can include an amplifier stage on the semiconductor substrate and coupled between the input matching network and the output matching network, wherein the amplifier stage includes a first transistor. The first transistor can include a first drain contact communicatively coupled to the output matching network. The first transistor can include a first gate contact communicatively coupled to the input matching network. The first transistor can include a second gate contact communicatively coupled to the input matching network, wherein the first drain contact is laterally interposed on the substrate between the first gate contact and the second gate contact.

An aspect of the disclosure provides a radio-frequency amplifier. The radio-frequency amplifier can include an input network having first and second terminals. The radio-frequency amplifier can include an output network having third and fourth terminals. The radio-frequency amplifier can include a substrate. The radio-frequency amplifier can include a first transistor on the substrate and having a first gate terminal coupled to the first terminal, a first source-drain terminal coupled to the third terminal, and a second source-drain terminal coupled to a reference voltage. The radio-frequency amplifier can include a second transistor on the substrate and having a second gate terminal coupled to the second terminal, a third source-drain terminal coupled to the fourth terminal, and a fourth source-drain terminal coupled to the second source-drain terminal and the reference voltage. The radio-frequency amplifier can include a third transistor on the substrate and having a third gate terminal coupled to the first terminal and the first gate terminal, a fifth source-drain terminal coupled to the fourth terminal and the third source-drain terminal, and a sixth source-drain terminal coupled to the reference voltage. The radio-frequency amplifier can include a fourth transistor on the substrate and having a fourth gate terminal coupled to the second terminal and the second gate terminal, a seventh source-drain terminal coupled to the third terminal and the first source-drain terminal, and an eighth source-drain terminal coupled to the reference voltage, wherein the first and second transistors are laterally interposed on the substrate between the third transistor and the fourth transistor.

An aspect of the disclosure provides an amplifier. The amplifier can include a first set of transistor cells that collectively share a first gate node, a first source node coupled to a reference voltage, and a first drain node. The transistor cells in the first set can include a first drain contact of the first drain node that extends along a longitudinal axis. The transistor cells in the first set can include a first source contact of the first source node that extends parallel to the longitudinal axis at a first side of the first drain contact. The transistor cells in the first set can include a second source contact of the first source node that extends parallel to the longitudinal axis at a second side of the first drain contact opposite the first side. The transistor cells in the first set can include a first gate contact of the first gate node that extends orthogonal to the longitudinal axis at a third side of the first drain contact. The transistor cells in the first set can include a second gate contact of the first gate node that extends orthogonal to the longitudinal axis at a fourth side of the first drain contact opposite the third side. The transistor cells in the first set can include a first plurality of gate lines of the first gate node that extend parallel to the longitudinal axis and that couple the first gate contact to the second gate contact. The transistor cells in the first set can include a first plurality of source lines of the first source node that extend orthogonal to the longitudinal axis and that couple the first source contact to the second source contact.

### BRIEF DESCRIPTION OF THE DRAWINGS

FIG. 1 is a diagram of an illustrative electronic device having wireless circuitry in accordance with some embodiments.

FIG. 2 is a diagram of illustrative wireless circuitry having radio-frequency amplifiers in accordance with some embodiments.

FIG. 3 is a diagram of illustrative transmit circuitry having a radio-frequency amplifier in accordance with some embodiments.

FIG. 4 is a circuit diagram of an illustrative radio-frequency amplifier having power transistors and capacitance neutralization transistors in accordance with some embodiments.

FIG. 5 is a top view of an illustrative transistor unit cell that may be used to form a transistor in a radio-frequency amplifier in accordance with some embodiments.

FIG. 6 is a cross-sectional side view of an illustrative transistor unit cell in accordance with some embodiments.

FIG. 7 is a top view of an illustrative radio-frequency amplifier having adjacent power transistors that are laterally interposed between capacitance neutralization transistors in accordance with some embodiments.

FIG. 8 includes plots of the gain and stability factor as a function of frequency for an illustrative radio-frequency amplifier in accordance with some embodiments.

FIG. 9 includes plots of the load impedance and passive efficiency as a function of frequency for an illustrative radio-frequency amplifier in accordance with some embodiments.

FIG. 10 is a circuit diagram of an illustrative multi-stage radio-frequency amplifier in accordance with some embodiments.

FIG. 11 is a plot of scattering parameters as a function of frequency for an illustrative multi-stage radio-frequency amplifier in accordance with some embodiments.

FIG. 12 is a plot of additional characteristics for an illustrative multi-stage radio-frequency amplifier in accordance with some embodiments.

FIG. 13 is a plot of error vector magnitude (EVM) as a function of output power level for an illustrative radio-frequency amplifier across different frequency, process corner, and temperature conditions in accordance with some embodiments.

### DETAILED DESCRIPTION

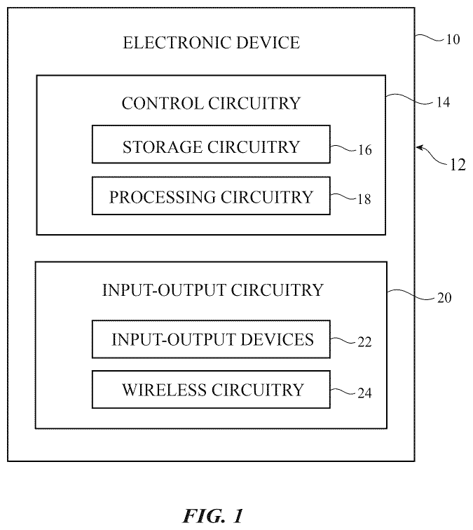

Electronic device 10 of FIG. 1 may be a computing device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses, goggles, a helmet, or other equipment worn on a user's head (e.g., an augmented, virtual, or mixed reality head-mounted display device), or another wearable or miniature device, a television, a computer display that does not contain an embedded computer, a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

As shown in the functional block diagram of FIG. 1, device 10 may include components located on or within an electronic device housing such as housing 12. Housing 12, which may sometimes be referred to as a case, may be formed from plastic, glass, ceramics, fiber composites, metal (e.g., stainless steel, aluminum, metal alloys, etc.), other suitable materials, or a combination of these materials. In some embodiments, parts or all of housing 12 may be formed from dielectric or other low-conductivity material (e.g., glass, ceramic, plastic, sapphire, etc.). In other embodiments, housing 12 or at least some of the structures that make up housing 12 may be formed from metal elements.

Device 10 may include control circuitry 14. Control circuitry 14 may include storage such as storage circuitry 16. Storage circuitry 16 may include hard disk drive storage, nonvolatile memory (e.g., flash memory or other electrically-programmable-read-only memory configured to form a solid-state drive), volatile memory (e.g., static or dynamic random-access-memory), etc. Storage circuitry 16 may include storage that is integrated within device 10 and/or removable storage media.

Control circuitry 14 may include processing circuitry such as processing circuitry 18. Processing circuitry 18 may be used to control the operation of device 10. Processing circuitry 18 may include on one or more processors such as microprocessors, microcontrollers, digital signal processors, host processors, baseband processor integrated circuits, application specific integrated circuits, central processing units (CPUs), graphics processing units (GPUs), etc. Control circuitry 14 may be configured to perform operations in device 10 using hardware (e.g., dedicated hardware or circuitry), firmware, and/or software. Software code for performing operations in device 10 may be stored on storage circuitry 16 (e.g., storage circuitry 16 may include non-transitory (tangible) computer readable storage media that stores the software code). The software code may sometimes be referred to as program instructions, software, data, instructions, or code. Software code stored on storage circuitry 16 may be executed by processing circuitry 18.

Control circuitry 14 may be used to run software on device 10 such as satellite navigation applications, internet browsing applications, voice-over-internet-protocol (VOIP) telephone call applications, email applications, media playback applications, operating system functions, etc. To support interactions with external equipment, control circuitry 14 may be used in implementing communications protocols. Communications protocols that may be implemented using control circuitry 14 include internet protocols, wireless local area network (WLAN) protocols (e.g., IEEE 802.11 protocols—sometimes referred to as Wi-Fi®), protocols for other short-range wireless communications links such as the Bluetooth® protocol or other wireless personal area network (WPAN) protocols, IEEE 802.11ad protocols (e.g., ultra-wideband protocols), cellular telephone protocols (e.g., 3G protocols, 4G (LTE) protocols, 3GPP Fifth Generation (5G) New Radio (NR) protocols, Sixth Generation (6G) protocols, sub-THz protocols, THz protocols, etc.), antenna diversity protocols, satellite navigation system protocols (e.g., global positioning system (GPS) protocols, global navigation satellite system (GLONASS) protocols, etc.), satellite communications (satcom) protocols, antenna-based spatial ranging protocols, optical communications protocols, or any other desired communications protocols. Each communications protocol may be associated with a corresponding radio access technology (RAT) that specifies the physical connection methodology used in implementing the protocol.

Device 10 may include input-output circuitry 20. Input-output circuitry 20 may include input-output devices 22. Input-output devices 22 may be used to allow data to be supplied to device 10 and to allow data to be provided from device 10 to external devices. Input-output devices 22 may include user interface devices, data port devices, and other input-output components. For example, input-output devices 22 may include touch sensors, displays (e.g., touch-sensitive and/or force-sensitive displays), light-emitting components such as displays without touch sensor capabilities, buttons (mechanical, capacitive, optical, etc.), scrolling wheels, touch pads, key pads, keyboards, microphones, cameras, buttons, speakers, status indicators, audio jacks and other audio port components, digital data port devices, motion sensors (accelerometers, gyroscopes, and/or compasses that detect motion), capacitance sensors, proximity sensors, magnetic sensors, force sensors (e.g., force sensors coupled to a display to detect pressure applied to the display), etc. In some configurations, keyboards, headphones, displays, pointing devices such as trackpads, mice, and joysticks, and other input-output devices may be coupled to device 10 using wired or wireless connections (e.g., some of input-output devices 22 may be peripherals that are coupled to a main processing unit or other portion of device 10 via a wired or wireless link).

Input-output circuitry 20 may include wireless circuitry 24 to support or perform radio-frequency signal transmission and/or reception for device 10. Wireless circuitry 24 may be used for wireless communications. Wireless communications performed by wireless circuitry 24 may include or involve wireless data communications (e.g., where wireless data is carried by radio-frequency signals conveyed between wireless circuitry 24 and other communications equipment bidirectionally or unidirectionally), radio-frequency signal transmission, radio-frequency signal reception, and/or radio-based spatial ranging/sensing (e.g., radio detection and ranging (radar) operations, shorter range object detection such as near-field radio-frequency signal-based object detection, etc.). Radio-frequency signals conveyed by wireless circuitry 24 may include or carry wireless data (e.g., organized into frames, packets, symbols, datagrams, etc.), radar or other spatial ranging waveforms, continuous wave signals, chirp signals, control signals, management signals, reference signals, beacon signals, tones, pulses/impulses, waveforms associated with one or more communications protocols, and/or any other radio-frequency waveforms or signals. Wireless circuitry 24 is sometimes also referred to herein as wireless communications circuitry 24, wireless communication circuitry 24, communications circuitry 24, or simply as circuitry 24. Wireless circuitry 24 may include one or more antennas. Wireless circuitry 24 may also include baseband processor circuitry, transceiver circuitry, amplifier circuitry, filter circuitry, switching circuitry, radio-frequency transmission lines, and/or any other circuitry for transmitting and/or receiving radio-frequency signals using the antenna(s). Some or all of the components of wireless circuitry 24 may be disposed on, mounted to, communicatively coupled to, and/or integrated within the same substrate (e.g., a printed circuit board, semiconductor substrate, chip, integrated circuit (IC), IC packages, etc.) or may be distributed between two or more substrates (e.g., printed circuit boards, semiconductor substrates, chips, ICs, IC packages, etc.).

Wireless circuitry 24 may transmit and/or receive radio-frequency signals within a corresponding frequency band at radio frequencies (sometimes referred to herein as a communications band or simply as a “band”). The frequency bands handled by wireless circuitry 24 may include wireless local area network (WLAN) frequency bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), a Wi-Fi® 7 band, and/or other Wi-Fi® bands (e.g., from 1875-5160 MHz), wireless personal area network (WPAN) frequency bands such as the 2.4 GHz Bluetooth® band or other WPAN communications bands, cellular telephone frequency bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), other centimeter or millimeter wave frequency bands between 10-100 GHz, sub-THz frequency bands between around 100 GHz and 10 THz (e.g., 6G bands), near-field communications (NFC) frequency bands (e.g., at 13.56 MHz), satellite navigation frequency bands (e.g., a GPS band from 1565 to 1610 MHz, a Global Navigation Satellite System (GLONASS) band, a BeiDou Navigation Satellite System (BDS) band, etc.), ultra-wideband (UWB) frequency bands that operate under the IEEE 802.15.4 protocol and/or other ultra-wideband communications protocols, satellite communications (satcom) bands (e.g., an IEEE C band (4-8 GHz), S band (2-4 GHz), L band (1-2 GHz), X band (8-12 GHz), W band (75-110 GHz), V band (40-75 GHz), K band (18-27 GHz), Kₐ band (26.5-40 GHz), Kᵤ band (12-18 GHz), etc.), unlicensed bands, communications bands under the family of 3GPP wireless communications standards, communications bands under the IEEE 802.XX family of standards, and/or any other desired frequency bands of interest.

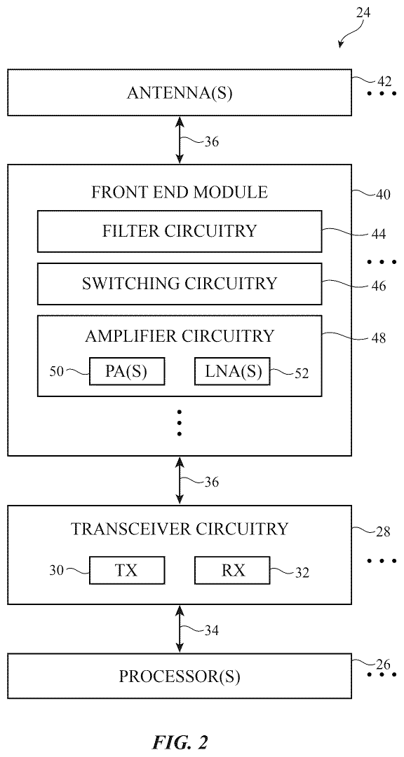

FIG. 2 is a diagram showing illustrative components within wireless circuitry 24. As shown in FIG. 2, wireless circuitry 24 may include a processor such as processor 26, radio-frequency (RF) transceiver circuitry such as radio-frequency transceiver 28, radio-frequency front end circuitry such as radio-frequency front end module (FEM) 40, and antenna(s) 42. Processor 26 may be a baseband processor, application processor, general purpose processor, microprocessor, microcontroller, digital signal processor, host processor, application specific signal processing hardware, or other type of processor. Processor 26 may be coupled to transceiver 28 over path 34. Transceiver 28 may be coupled to antenna 42 via radio-frequency transmission line path 36. Radio-frequency front end module 40 may be disposed on radio-frequency transmission line path 36 between transceiver 28 and antenna 42.

In the example of FIG. 2, wireless circuitry 24 is illustrated as including only a single processor 26, a single transceiver 28, a single front end module 40, and a single antenna 42 for the sake of clarity. In general, wireless circuitry 24 may include any desired number of processors 26, any desired number of transceivers 28, any desired number of front end modules 40, and any desired number of antennas 42. Each processor 26 may be coupled to one or more transceiver 28 over respective paths 34. Each transceiver 28 may include a transmitter circuit 30 configured to output uplink signals to antenna 42, may include a receiver circuit 32 configured to receive downlink signals from antenna 42, and may be coupled to one or more antennas 42 over respective radio-frequency transmission line paths 36. Each radio-frequency transmission line path 36 may have a respective front end module 40 disposed thereon. If desired, two or more front end modules 40 may be disposed on the same radio-frequency transmission line path 36. If desired, one or more of the radio-frequency transmission line paths 36 in wireless circuitry 24 may be implemented without any front end module disposed thereon.

Radio-frequency transmission line path 36 may be coupled to an antenna feed on antenna 42. The antenna feed may, for example, include a positive antenna feed terminal and a ground antenna feed terminal. Radio-frequency transmission line path 36 may have a positive transmission line signal path that is coupled to the positive antenna feed terminal on antenna 42. Radio-frequency transmission line path 36 may have a ground transmission line signal path that is coupled to the ground antenna feed terminal on antenna 42. This example is illustrative and, in general, antennas 42 may be fed using any desired antenna feeding scheme. If desired, antenna 42 may have multiple antenna feeds that are coupled to one or more radio-frequency transmission line paths 36.

Radio-frequency transmission line path 36 may include transmission lines that are used to route radio-frequency antenna signals within device 10 (FIG. 1). Transmission lines in device 10 may include coaxial cables, microstrip transmission lines, stripline transmission lines, edge-coupled microstrip transmission lines, edge-coupled stripline transmission lines, transmission lines formed from combinations of transmission lines of these types, etc. Transmission lines in device 10 such as transmission lines in radio-frequency transmission line path 36 may be integrated into rigid and/or flexible printed circuit boards.

In performing wireless transmission, processor 26 may provide transmit signals (e.g., digital or baseband signals) to transceiver 28 over path 34. Transceiver 28 may further include circuitry for converting the transmit (baseband) signals received from processor 26. For example, transceiver circuitry 28 may include mixer circuitry for up-converting (or modulating) the transmit (baseband) signals to radio frequencies prior to transmission over antenna 42. The example of FIG. 2 in which processor 26 communicates with transceiver 28 is illustrative. In general, transceiver 28 may communicate with a baseband processor, an application processor, general purpose processor, a microcontroller, a microprocessor, or one or more processors within circuitry 18. Transceiver circuitry 28 may also include digital-to-analog converter (DAC) and/or analog-to-digital converter (ADC) circuitry for converting signals between digital and analog domains. Transceiver 28 may use transmitter (TX) 30 to transmit the radio-frequency signals over antenna 42 via radio-frequency transmission line path 36 and front end module 40. Antenna 42 may transmit the radio-frequency signals to external wireless equipment by radiating the radio-frequency signals into free space.

In performing wireless reception, antenna 42 may receive radio-frequency signals from the external wireless equipment. The received radio-frequency signals may be conveyed to transceiver 28 via radio-frequency transmission line path 36 and front end module 40. Transceiver 28 may include circuitry such as receiver (RX) 32 for receiving signals from front end module 40 and for converting the received radio-frequency signals into corresponding baseband signals. For example, transceiver 28 may include mixer circuitry for down-converting (or demodulating) the received radio-frequency signals to baseband frequencies prior to conveying the received signals to processor 26 over path 34.

Front end module (FEM) 40 may include radio-frequency front end circuitry that operates on the radio-frequency signals conveyed (transmitted and/or received) over radio-frequency transmission line path 36. FEM 40 may, for example, include front end module (FEM) components such as radio-frequency filter circuitry 44 (e.g., low pass filters, high pass filters, notch filters, band pass filters, multiplexing circuitry, duplexer circuitry, diplexer circuitry, triplexer circuitry, etc.), switching circuitry 46 (e.g., one or more radio-frequency switches), radio-frequency amplifier circuitry 48 (e.g., one or more power amplifiers 50 and/or one or more low-noise amplifier circuits 52), signal attenuators, impedance matching circuitry (e.g., circuitry that helps to match the impedance of antenna 42 to the impedance of radio-frequency transmission line 36), antenna tuning circuitry (e.g., networks of capacitors, resistors, inductors, and/or switches that adjust the frequency response of antenna 42), radio-frequency coupler circuitry, charge pump circuitry, power management circuitry, digital control and interface circuitry, and/or any other desired circuitry that operates on the radio-frequency signals transmitted and/or received by antenna 42. Each of the front end module components may be mounted to a common (shared) substrate such as a rigid printed circuit board substrate or flexible printed circuit substrate. If desired, the various front end module components may also be integrated into a single integrated circuit chip. If desired, amplifier circuitry 48 and/or other components in front end 40 such as filter circuitry 44 may also be implemented as part of transceiver circuitry 28.

Filter circuitry 44, switching circuitry 46, amplifier circuitry 48, and other circuitry may be disposed along radio-frequency transmission line path 36, may be incorporated into FEM 40, and/or may be incorporated into antenna 42 (e.g., to support antenna tuning, to support operation in desired frequency bands, etc.). These components, sometimes referred to herein as antenna tuning components, may be adjusted (e.g., using control circuitry 14) to adjust the frequency response and wireless performance of antenna 42 over time.

Transceiver 28 may be separate from front end module 40. For example, transceiver 28 may be formed on another substrate such as the main logic board of device 10, a rigid printed circuit board, or flexible printed circuit that is not a part of front end module 40. While control circuitry 14 is shown separately from wireless circuitry 24 in the example of FIG. 1 for the sake of clarity, wireless circuitry 24 may include processing circuitry that forms a part of processing circuitry 18 and/or storage circuitry that forms a part of storage circuitry 16 of control circuitry 14 (e.g., portions of control circuitry 14 may be implemented on wireless circuitry 24). As an example, processor 26 and/or portions of transceiver 28 (e.g., a host processor on transceiver 28) may form a part of control circuitry 14. Control circuitry 14 (e.g., portions of control circuitry 14 formed on processor 26, portions of control circuitry 14 formed on transceiver 28, and/or portions of control circuitry 14 that are separate from wireless circuitry 24) may provide control signals (e.g., over one or more control paths in device 10) that control the operation of front end module 40.

Transceiver 28 may include wireless local area network transceiver circuitry that handles WLAN communications bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network transceiver circuitry that handles the 2.4 GHz Bluetooth® band or other WPAN communications bands, cellular telephone transceiver circuitry that handles cellular telephone bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, 6G bands above 100 GHz, etc.), near-field communications (NFC) transceiver circuitry that handles near-field communications bands (e.g., at 13.56 MHz), satellite navigation receiver circuitry that handles satellite navigation bands (e.g., a GPS band from 1565 to 1610 MHz, a Global Navigation Satellite System (GLONASS) band, a BeiDou Navigation Satellite System (BDS) band, etc.), ultra-wideband (UWB) transceiver circuitry that handles communications using the IEEE 802.15.4 protocol and/or other ultra-wideband communications protocols, and/or any other desired radio-frequency transceiver circuitry for covering any other desired communications bands of interest.

Wireless circuitry 24 may include one or more antennas such as antenna 42. Antenna 42 may be formed using any desired antenna structures. For example, antenna 42 may be an antenna with a resonating element that is formed from loop antenna structures, patch antenna structures, inverted-F antenna structures, slot antenna structures, planar inverted-F antenna structures, helical antenna structures, monopole antennas, dipoles, hybrids of these designs, etc. Two or more antennas 42 may be arranged into one or more phased antenna arrays (e.g., for conveying radio-frequency signals at millimeter wave frequencies). Parasitic elements may be included in antenna 42 to adjust antenna performance. Antenna 42 may be provided with a conductive cavity that backs the antenna resonating element of antenna 42 (e.g., antenna 42 may be a cavity-backed antenna such as a cavity-backed slot antenna).

As described above, front end module 40 may include one or more power amplifiers (PAs) 50 in the transmit (uplink) path. A power amplifier 50 (sometimes referred to as a radio-frequency power amplifier, transmit amplifier, or amplifier) may be configured to amplify a radio-frequency signal without changing the signal shape, format, or modulation. Amplifier 50 may, for example, be used to provide 10 dB of gain, 20 dB of gain, 10-20 dB of gain, less than 20 dB of gain, more than 20 dB of gain, or other suitable amounts of gain.

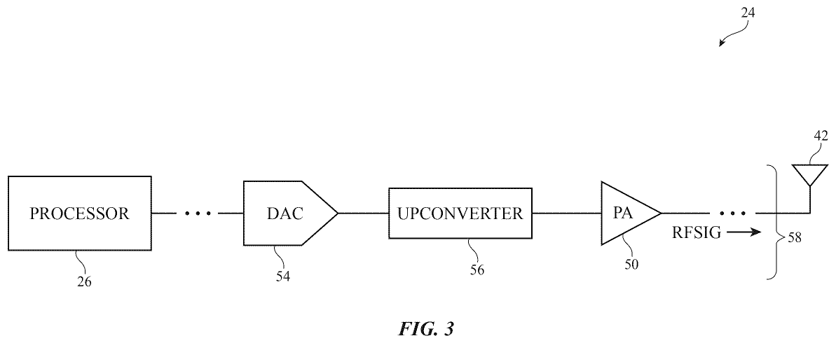

FIG. 3 is a diagram of an illustrative transmit path 58 of wireless circuitry 24. Transmit path 58 is sometimes also referred to herein as transmit chain 58 or transmit circuitry 58. As shown in FIG. 3, wireless circuitry 24 may include processing circuitry such as one or more processors 26, digital-to-analog converter (DAC) circuitry such as DAC 54, upconversion circuitry such as upconverter 56 (e.g., one or more mixers), radio-frequency amplifier circuitry such as radio-frequency amplifier 50 (e.g., a power amplifier), and an antenna 42 configured to radiate radio-frequency signals output by amplifier 50. Additional components (not shown) may also be disposed at different locations along transmit path 58 if desired.

Amplifier 50 may be disposed on FEM 40 or in transceiver circuitry 28 of FIG. 2. Processor(s) 26 may represent one or more processors such as a baseband processor, an application processor, a digital signal processor, a microcontroller, a microprocessor, a central processing unit (CPU), a programmable device, a combination of these circuits, and/or one or more processors within circuitry 18 of FIG. 1. Processor(s) 26 may be configured to generate a digital baseband signal Dbb (e.g., a stream of digital data bits at baseband). Signal Dbb is sometimes referred to as a digital signal or a transmit signal. As examples, the signal Dbb generated by processor(s) 26 may include in-phase (I) and quadrature-phase (Q) signals, radius and phase signals, a vector input, or other digitally coded signals.

DAC 54 may convert signal Dbb from a digital signal into an analog signal (e.g., from the digital domain to the analog domain). Upconverter 56 may upconvert (modulate) the signal from baseband to radio-frequencies. Amplifier 50 may amplify the upconverted signal as radio-frequency signal RFSIG. Antenna 42 may radiate radio-frequency signal RFSIG. DAC 54 may be coupled between processor 26 and upconverter 56, may be coupled between upconverter 56 and amplifier 50 or, if desired, upconverter 56 and DAC 54 may be integrated into a single radio-frequency converter block (e.g., an RFDAC) that performs conversion both from the digital domain to the analog domain and from baseband to radio frequencies. If desired, DAC 54, upconverter 56, and/or an RF DAC may include multiple different cells (e.g., DAC cells, RF DAC cells, etc.) that operate on the signals conveyed via transmit path 58. The input of amplifier 50 configured to receive radio-frequency signals from upconverter 56 is also referred to or defined herein as a radio-frequency input (port) of amplifier 50. Radio frequencies can range from a few kHz to tens of THz.

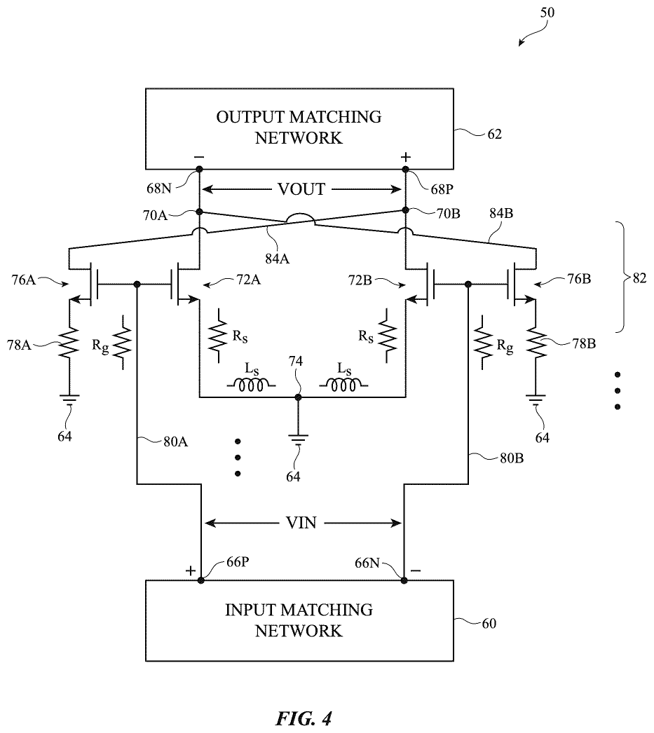

FIG. 4 is a circuit diagram of amplifier 50 (e.g., in an illustrative implementation where amplifier 50 includes a common source amplifier). As shown in FIG. 4, amplifier 50 may include input impedance matching circuitry such as input matching network 60 and may include output impedance matching circuitry such as output matching network 62. Matching networks 60 and 62 may each include one or more transformers, baluns, filters, signal couplers, coupled lines, resistive components, inductive components, capacitive components, and/or any other desired impedance matching circuitry.

Amplifier 50 may also have an amplifier core (e.g., a power amplifier core) that includes one or more amplifier stages 82 (e.g., common source amplifier stages or elements) coupled between input matching network 60 and output matching network 62. In the example of FIG. 4, amplifier 50 is illustrated as including a single amplifier stage 82 for the sake of simplicity (e.g., a power amplifier or power transistor stage that is sometimes also referred to herein as PA stage 82 or power transistor stage 82). In general, amplifier 50 may include two stages or more than two stages coupled between the input and output matching networks.

Amplifier stage 82 may include a pair of power transistors 72 such as a first power transistor 72A and a second power transistor 72B. If desired, amplifier stage 82 may also include a pair of capacitance neutralization transistors 76 for power transistors 72 such as a first capacitance neutralization transistor 76A and a second capacitance neutralization transistor 76B. Power transistors 72A and 72B and capacitance neutralization transistors 76A and 76B may be n-channel metal-oxide-semiconductor (NMOS) transistors, as one example. More generally, transistors 72A, 72B, 76A, and 76B may include p-channel metal-oxide-semiconductor (PMOS) transistors, NMOS transistors, and/or other types of transistors.

Input matching network 60 may have an input port that is communicatively coupled to the output of upconverter 56 (FIG. 3). Input matching network 60 may have an output port 66 that is sometimes also referred to herein as the input port 66 of amplifier stage(s) within amplifier 50. The output port 66 of input matching network 60 may be, for example, a differential signal port that includes a first (positive) terminal 66P and a second (negative) terminal 66N (sometimes also referred to herein as output terminals of input matching network 60 or input terminals of the amplifier stage(s) of amplifier 50). During signal transmission, input matching network 60 may receive a radio-frequency signal from upconverter 56 (FIG. 3) and may output the radio-frequency signal at its output port 66. The radio-frequency signal output by input matching network 60 may, for example, be represented by an input voltage VIN between input terminals 66P and 66N.

Output matching network 62 may have an output port that is communicatively coupled to antenna 42 (FIG. 3). Output matching network 62 may output radio-frequency signal RFSIG (FIG. 3) at its output port. Output matching network 62 may also have an input port 68 that is sometimes also referred to herein as the output port 68 of the amplifier stage(s) within amplifier 50. The input port 68 of output matching network 62 may be, for example, a differential signal port that includes a first (positive) terminal 68P and a second (negative) terminal 68N (sometimes also referred to herein as input terminals of output matching network 62 or output terminals of the amplifier stage(s) of amplifier 50). During signal transmission, the amplifier stage(s) of amplifier 50 (e.g., at least amplifier stage 82) may amplify the radio-frequency signal transmitted over input port 66 (e.g., at input voltage VIN) to produce a corresponding amplified output voltage VOUT between terminals 68N and 68P. Output matching network 62 may transmit output voltage VOUT as radio-frequency signal RFSIG of FIG. 3.

The power transistor 72A of amplifier stage 82 may be coupled between terminal 66P of input matching network 60 and terminal 68N of output matching network 60. The power transistor 72B of amplifier stage 82 may be coupled between terminal 66N of input matching network 60 and terminal 68P of output matching network 60. The terms “source” and “drain” are sometimes used interchangeably when referring to current-conducting terminals or nodes of a metal-oxide-semiconductor (MOS) transistor. The source and drain terminals or nodes of a MOS transistor are therefore sometimes referred to as “source-drain” terminals or “source-drain” nodes (e.g., a transistor has a gate terminal or node, a first source-drain terminal or node, and a second source-drain terminal or node). The source, drain, and gate terminals of a transistor are sometimes also referred to interchangeably herein as source, drain, and gate nodes of the transistor, or more simply as the source, drain, and gate of the transistor.

Power transistor 72A may have a first source-drain node (e.g., a drain node) coupled to terminal 68N of output matching network 62 and may have a second source-drain node (e.g. a source node) coupled to reference voltage 64. Reference voltage 64 may be a ground voltage, VSS, or another reference potential. Power transistor 72B may have a first source-drain node (e.g., a drain node) coupled to terminal 68P of output matching network 62 and may have a second source-drain node (e.g. a source node) coupled to reference voltage 64. Put differently, the second source-drain nodes (e.g., the source nodes) of power transistors 72A and 72B may both be coupled to the same circuit node 74 (sometimes also referred to herein as reference node 74) and circuit node 74 may be coupled to reference potential 64 (e.g., the source terminals of both power transistors 72A and 72B may be coupled together and to reference voltage 64, configuring power transistors 72A and 72B to form a pair of common source transistors).

The gate terminal of power transistor 72A may be coupled to terminal 66P of input matching network 60 over signal line 80A. The gate terminal of power transistor 72B may be coupled to terminal 66N of input matching network 60 over signal line 80N. Signal lines 80A and 80B are sometimes also referred to herein as signal conductors 80A/80B, input signal lines 80A/80B, input signal conductors 80A/80B, input paths 80A/80B, or signal paths 80A/80B. During signal transmission, the voltage applied to the gate terminals of power transistors 72A and 72B is given by the input voltage VIN transmitted via terminals 66P and 66N. When the magnitude of the voltage supplied to the gate terminals of power transistors 72A and 72B changes, the amount of current flowing between the source-drain terminals of power transistors 72A and 72B changes, producing a corresponding output voltage VOUT between the terminals 68N and 68P of output matching network 62.

Capacitance neutralization transistors 76A and 76B may be cross-coupled around power transistors 72A and 72B and may be configured to neutralize the feedback effect (e.g., the Miller effect) of the gate-to-drain capacitance Cgd in power transistors 72A and 72B. Capacitance neutralization transistor 76A may have a gate node coupled to the gate node of power transistor 72A and signal line 80A (e.g., signal line 80A, the gate node of power transistor 72A, and the gate node of capacitance neutralization transistor 76A may all be coupled to a shared circuit node). A first source-drain node (e.g., the drain node) of capacitance neutralization transistor 76A may be coupled to the first source-drain node (e.g., the drain node) of power transistor 72B and to terminal 68P of output matching network 62 by conductive line 84A (e.g., conductive line 84A, the drain node of power transistor 72B, and terminal 68P of output matching network 62 may all be coupled to the same shared circuit node 70B).

Similarly, capacitance neutralization transistor 76B may have a gate node coupled to the gate node of power transistor 72B and signal line 80B (e.g., signal line 80B, the gate node of power transistor 72B, and the gate node of capacitance neutralization transistor 76B may all be coupled to a shared circuit node). A first source-drain node (e.g., the drain node) of capacitance neutralization transistor 76B may be coupled to the first source-drain node (e.g., the drain node) of power transistor 72A and to terminal 68N of output matching network 62 by conductive line 84B (e.g., conductive line 84B, the drain node of power transistor 72A, and terminal 68N of output matching network 62 may all be coupled to the same shared circuit node 70A). When coupled to power transistors 72A and 72B in this way, capacitance neutralization transistors 76A and 76B may neutralize the Miller effect, helping to increase the power gain, reverse isolation, and stability of amplifier 50 over a relatively wide bandwidth. This implementation is illustrative and non-limiting and, if desired, capacitance neutralization transistors 76A and 76B may be omitted from amplifier 50, capacitance neutralization transistors 76A and 76B may be provided with other implementations, and/or amplifier 50 may be implemented using other amplifier architectures. In some implementations, for example, resistors 78A and 78B may be omitted. In these implementations, if desired, the source and drain nodes of capacitance neutralization transistor 76A may both be coupled to circuit node 70B and the source and drain nodes of capacitance neutralization transistor 76B may both be coupled to circuit node 70A. The example of FIG. 4 in which amplifier 50 is implemented as a common source amplifier is illustrative and non-limiting. Amplifier 50 need not be implemented as a common source amplifier and may, if desired, be implemented using other amplifier topologies. For example, amplifier 50 may be implemented as a cascode amplifier (e.g., having a common gate stage fed by a common source stage, where the common source stage includes stage 82 of FIG. 4), may be implemented using a stacked topology, and/or may be implemented using any desired amplifier topology having a common source element or stage (e.g., having power transistors 72A and 72B and optionally capacitance neutralization transistors 76A and 76B of FIG. 4).

In practice, it may be desirable to transmit radio-frequency signal RFSIG at frequencies in a D-band spectrum due to its potential to address demand for extreme data rates and its diverse range of applications across a variety of industries. Nanometer-scale complementary metal-oxide-semiconductor (CMOS) technology helps to achieve low cost in volume and high integration with high speed baseband and digital signal processor (DSP) circuits. It can be difficult to design satisfactory amplifiers for these frequencies using certain process technologies such as a fin field effect transistor (finFET) technology. This is because radio-frequency performance may become degraded due to an increase in device and interconnect parasitics. As a large transistor width may be needed to deliver radio-frequency power, this effect can become even more pronounced due to long-length interconnects. In addition, it can be difficult to design satisfactory output matching networks for D-band amplifiers that utilize finFET technology. This is because the required inductance to resonate out the device capacitance scales down rapidly with both an increase in capacitance and frequency. Further decreasing inductance can cause a reduced coupling coefficient and deteriorated insertion loss.

Device and interconnect parasitics are two dominant causes that can degrade the gain, output power, and/or efficiency of amplifier 50 at relatively high frequencies. At D-band frequencies in particular (e.g., around 110 GHz to around 170 GHz), the operating frequency approaches a significant fraction of the cutoff frequency for the transistors in the amplifier (e.g., FT/FMAX). Device parasitics present a large portion of the total impedance at each node, which can substantially degrade radio-frequency performance. Layout design becomes important to minimize parasitics in each transistor, especially gate resistance, source resistance/inductance, and gate-to-drain capacitance. In parallel, large power cell sizes can introduce long interconnects around the transistors. The associated parasitic resistances and inductances, especially those in the source network, which are not scaled or even become worse as technology scales, can substantially degenerate the transistor and thus limit the power gain and output power of amplifier 50. It would therefore also be desirable to be able to minimize degradation due to interconnect length during layout optimization.

The device and interconnect parasitics in amplifier 50 may, for example, include a parasitic gate resistance R_{g} coupled between the gate nodes of each of transistors 76A and 72A and terminal 66P, a parasitic gate resistance R_{g} coupled between the gate nodes of each of transistors 76B and 72B and terminal 66N, a parasitic source resistance Rₛ coupled between the source node of each of power transistors 72A/72B and reference voltage 64, and a parasitic source inductance Lₛ coupled between the source node of each of power transistors 72A/72B and reference voltage 64. Both parasitic source resistance Rₛ and parasitic source inductance Lₛ may substantially degrade the power gain of amplifier 50 due to the degeneration effect (e.g., gain may be degraded by 0.8 dB or greater for every 1 Ohm of resistance in parasitic source resistance Rₛ or every 1 pH of inductance in parasitic source inductance Lₛ). In addition, parasitic gate resistance R_{g} can degrade the gain of amplifier 50 by as much as 0.6 dB or higher for every 1 Ohm of resistance in parasitic gate resistance R_{g}. To help minimize these device and interconnect parasitics, as described below, amplifier 50 may be implemented using double-gate connections at both the transistor unit cell level and the amplifier stage level and may be provided with a common-mode-differential-mode decoupled source network at the amplifier stage level.

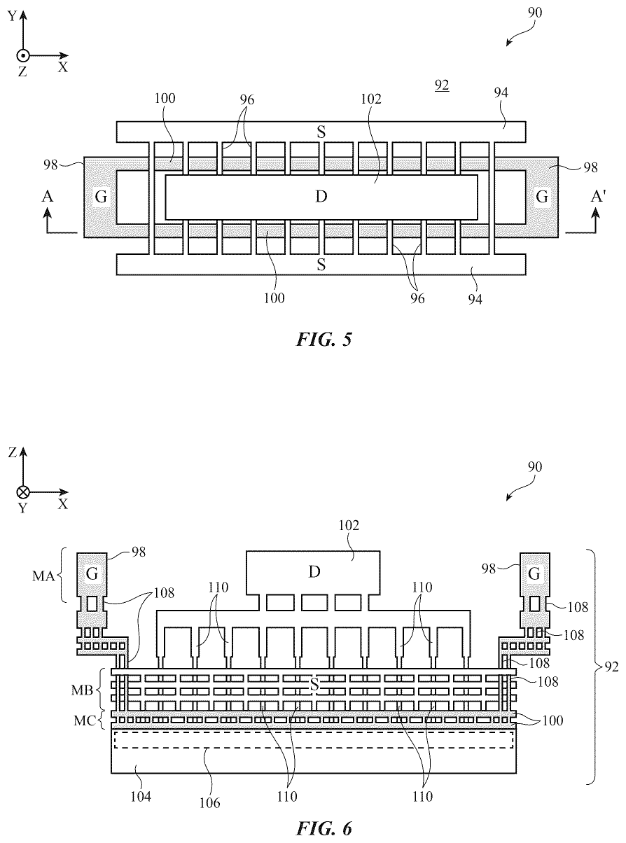

FIG. 5 is a top (layout) view of an illustrative transistor unit cell 90 that may be implemented in amplifier 50. Transistor unit cells such as transistor unit cell 90 of FIG. 5 may, for example, be used to form one or more of the transistors 76A, 72A, 72B, and 76B in amplifier stage 82. A single transistor in amplifier stage 82 (e.g., transistor 76A, 72A, 72B, or 76B) may include a set of one or more transistor unit cells 90 of FIG. 5 that are coupled together (e.g., a row or column of transistor unit cells having gate nodes that are coupled together to effectively form the gate node of the transistor, source nodes that are coupled together to effectively form the source node of the transistor, and/or drain nodes that are coupled together to effectively form the drain node of the transistor).

As shown in FIG. 5, transistor unit cell 90 (sometimes also referred to herein as transistor cell 90) may be fabricated on and/or within a corresponding substrate 92 (e.g., a semiconductor substrate such as an integrated circuit wafer, chip, or die). Transistor unit cell 90 may, for example, form part of a finFET in implementations where the corresponding transistor is fabricated using a finFET process technology.

Transistor unit cell 90 may include a drain node D (e.g., forming some or all of the drain node or terminal of the corresponding transistor), a gate node G (e.g., forming some or all of the gate node or terminal of the corresponding transistor), and a source node S (e.g., forming some or all of the source node or terminal of the corresponding transistor). Gate node G may be formed from a first set of one or more interconnected conductors (e.g., conductive traces in one or more metallization layers of substrate 92 and/or one or more conductive vias extending vertically through substrate 92 parallel to the Z-axis). Source node S may be formed from a second set of one or more interconnected conductors (e.g., conductive traces in one or more metallization layers of substrate 92 and/or one or more conductive vias). Drain node D may be formed from a third set of one or more interconnected conductors (e.g., conductive traces in one or more metallization layers of substrate 92 and/or one or more conductive vias extending vertically through substrate 92).

Drain node D may include an elongated drain contact 102. Drain contact 102 is sometimes also referred to herein as drain conductor 102 or drain connection 102. Drain contact 102 may be formed from a continuous and elongated conductor or conductive trace in a corresponding metallization layer of substrate 92. Drain contact 102 may have an elongated shape that extends along a linear longitudinal axis parallel to the X-axis of FIG. 5. Drain contact 102 may, for example, have a rectangular shape with first, second, third, and fourth edges. The first and second edges extend orthogonal to the longitudinal axis (e.g., parallel to the Y-axis of FIG. 5). The third and fourth edges extend in parallel from the first edge to the second edge (e.g., parallel to the longitudinal axis of drain contact 102 and parallel to the X-axis of FIG. 5, orthogonal to the first and second edges). The third and fourth edges are longer than the first and second edges (e.g., configuring the drain contact to exhibit an elongated linear or rectangular shape).

Drain contact 102 may be electrically/communicatively coupled or connected to other components in amplifier 50. For example, when transistor unit cell 90 of FIG. 5 is implemented in capacitance neutralization transistor 76A of FIG. 4, drain contact 102 may be coupled to circuit node 70B, the drain node of power transistor 72B, and terminal 68P. When transistor unit cell 90 of FIG. 5 is implemented in capacitance neutralization transistor 76B of FIG. 4, drain contact 102 may be coupled to circuit node 70A, the drain node of power transistor 72A, and terminal 68N. When transistor unit cell 90 of FIG. 5 is implemented in power transistor 72A of FIG. 4, drain contact 102 may be coupled to circuit node 70A, the drain node of capacitance neutralization transistor 76B, and terminal 68N. When transistor unit cell 90 of FIG. 5 is implemented in power transistor 72B of FIG. 4, drain contact 102 may be coupled to circuit node 70B, the drain node of capacitance neutralization transistor 76A, and terminal 68P.

Source node S may include a first elongated source contact 94 and a second elongated source contact 94. Source contacts 94 are sometimes also referred to herein as source conductors 94 or source connections 94. Each source contact 94 may be formed from a respective continuous and elongated conductor or conductive trace in a corresponding metallization layer of substrate 92 (e.g., different from the metallization layer used to form drain contact 102). Each source contact 94 may have an elongated shape that extends along a linear longitudinal axis parallel to the X-axis of FIG. 5. The longitudinal axis of each source contact 94 may extend parallel to the longitudinal axis of drain contact 102. The first source contact 94 may laterally face the third edge of drain contact 102 and may extend along, facing, and parallel to the third edge of drain contact 102. The second source contact 94 may laterally face the fourth edge of drain contact 102 and may extend along, facing, and parallel to the fourth edge of drain contact 102 (e.g., each source contact 94 is elongated and extending parallel to drain contact 102). Each source contact 94 may, for example, have first and second edges extending parallel to the Y-axis and the first and second edges of drain contact 102 and may have third and fourth edges extending from the first edge to the second edge parallel to the X-axis and the third and fourth edges of drain contact 102. The third and fourth edges of each source contact 94 are longer than the first and second edges of that source contact 94 (e.g., configuring each source contact 94 to have an elongated shape parallel to the X-axis). If desired, each source contact 94 may be longer (e.g., parallel to the X-axis) than drain contact 102.

Source node S may also include a set of source lines 96 extending from the first source contact 94 to the second source contact 94. Source lines 96 may extend along parallel longitudinal axes that are orthogonal to the longitudinal axes of source contacts 94. Source lines 96 may include conductors and/or conductive traces in one or more metallization layers of substrate 92 and/or may include conductive vias extending through substrate 92. Each source line 96 may electrically couple the first source contact 94 to the second source contact 94 (e.g., at a respective location along the length of the source contacts). This may configure source contacts 94 and source lines 96 to collectively form a single electrically continuous source node S of transistor unit cell 90. Each source line 96 may extend parallel to the Y-axis and orthogonal to source contacts 94 and drain contact 102. Source lines 96 are sometimes also referred to as source conductors 96 or fingers 96. Each source contact 94 may be wider (e.g., measured orthogonal to its longitudinal axis) than each source line 96 (e.g., each source contact 94 may be formed from a wide metal track on substrate 92). Drain contact 102 may overlap (e.g., as viewed in the −Z direction) at least some of the source lines 96 of source node S. Drain contact 102 may be non-overlapping with respect to the first and second source contacts 94.

Both source contacts 94 may be electrically/communicatively coupled or connected to other components in amplifier 50. For example, when transistor unit cell 90 of FIG. 5 is implemented in capacitance neutralization transistor 76A of FIG. 4, source contacts 94 may be coupled to reference voltage 64 through resistor 78A. When transistor unit cell 90 of FIG. 5 is implemented in capacitance neutralization transistor 76B of FIG. 4, source contacts 94 may be coupled to reference voltage 64 through resistor 78B. When transistor unit cell 90 of FIG. 5 is implemented in power transistor 72A of FIG. 4, source contacts 94 may be coupled to circuit reference voltage 64 and the source node of power transistor 72B (e.g., at circuit node 74 of FIG. 4). When transistor unit cell 90 of FIG. 5 is implemented in power transistor 72B of FIG. 4, source contacts 94 may be coupled to circuit reference voltage 64 and the source node of power transistor 72A (e.g., at circuit node 74 of FIG. 4).

In some implementations, the gate node G of transistor unit cell 90 includes only a single gate contact at a single side of the transistor unit cell (e.g., facing only the first edge of source contacts 94 and drain contact 102). To reduce the effective gate resistance of transistor unit cell 90 (e.g., by a factor of 4 or greater), the gate node G of transistor unit cell 90 may include a pair of gate contacts 98 on either side of the transistor unit cell. For example, as shown in FIG. 5, gate node G may include a first gate contact 98 and a second gate contact 98 on opposing sides of drain contact 102. The first gate contact 98 may face the first edge of drain contact 102. The second gate contact 98 may face the second edge of gate contact 98. Drain contact 102 may be laterally interposed between the first and second gate contacts 98. If desired, gate contacts 98 may extend along respective parallel longitudinal axes. The longitudinal axes of gate contacts 98 may extend orthogonal to the longitudinal axes of source contacts 94, orthogonal to the longitudinal axis of drain contact 102, parallel to the longitudinal axes of source lines 96, and parallel to the Y-axis. The gate terminals may have a length along their longitudinal axes that is less than the length of source contacts 94 and drain contact 102. Each gate contact 98 may have a length (e.g., measured parallel to the Y-axis) that is greater than the width (e.g., measured parallel to the Y-axis) of drain contact 102.

Each gate contact 98 may be formed from a respective continuous and elongated conductor or conductive trace in a corresponding metallization layer of substrate 92. If desired, gate contacts 98 may be formed from the same metallization layer(s) as drain contact 102. Gate node G may also include a set of two or more gate lines 100 extending from the first gate contact 98 to the second gate contact 98. Each gate line 100 may include conductors or conductive traces in one or more metallization layers of substrate 92 and/or one or more conductive vias extending through substrate 92. If desired, gate lines 100 may overlap source lines 96 but not drain contact 102 (e.g., gate lines 100 may be non-overlapping with respect to drain contact 102 when viewed in the −Z direction). Each gate line 100 may extend along a respective longitudinal axis parallel to the longitudinal axes of source contacts 94 and drain contact 102 and orthogonal to the longitudinal axes of gate contacts 98 and source lines 96. Each gate line 100 may electrically couple the first gate contact 98 to the second gate contact 98, configuring gate contacts 98 and gate lines 100 to collectively form a single electrically continuous gate node G of transistor unit cell 90 (e.g., a ring-shaped gate node that laterally surrounds drain contact 102 when viewed in the −Z direction).

Both the first and second source contacts 94 of transistor unit cell 90 may be electrically/communicatively coupled or connected to other components in amplifier 50. For example, when transistor unit cell 90 of FIG. 5 is implemented in capacitance neutralization transistor 76A of FIG. 4, source contacts 94 may be coupled to reference voltage 64 through resistor 78A. When transistor unit cell 90 of FIG. 5 is implemented in capacitance neutralization transistor 76B of FIG. 4, source contacts 94 may be coupled to reference voltage 64 through resistor 78B. When transistor unit cell 90 of FIG. 5 is implemented in power transistor 72A of FIG. 4, source contacts 94 may be coupled to circuit reference voltage 64 and the source node of power transistor 72B (e.g., at circuit node 74 of FIG. 4). When transistor unit cell 90 of FIG. 5 is implemented in power transistor 72B of FIG. 4, source contacts 94 may be coupled to circuit reference voltage 64 and the source node of power transistor 72A (e.g., at circuit node 74 of FIG. 4).

FIG. 6 is a cross-sectional side view of transistor unit cell 90 (e.g., as viewed along line AA′ of FIG. 5). As shown in FIG. 6, the first gate contact 98, drain contact 102, and the second gate contact 98 of transistor unit cell 90 may be formed from a metallization layer MA in substrate 92 (e.g., a top or uppermost metallization layer of substrate 92). Drain terminal 102 may be laterally interposed between the first gate contact 98 and the second gate contact 98 (e.g., gate contacts 98 may face opposing sides or edges of drain contact 102). Gate node G may also include a set of conductive vias 108 that extend downwards from gate terminals 98 through substrate 92 to substrate portion 104 (e.g., a semiconductor bulk region of substrate 92). Substrate portion 104 may include transistor device 106 for transistor unit cell 90. Transistor device 106 may, for example, include one or more doped semiconductor regions of substrate portion 104 and may form the channel for transistor unit cell 90 and/or the corresponding transistor containing transistor unit cell 90. Transistor device 106 is sometimes also referred to herein as oxide diffusion (OD) region 106, channel 106, or simply as device 106.

The conductive vias 108 of gate node G may electrically couple the first and second gate terminals 98 to the gate lines 100 of gate node G. Gate lines 100 may be formed from a set of one or more metallization layers MC of substrate 92. If desired, gate lines 100 may also include one or more conductive vias that electrically couple multiple metallization layers MC together. As shown in FIG. 6, gate lines 100 may laterally extend from the first gate contact 98 to the second gate contact 98 of transistor unit cell 90. A first end of gate lines 100 may be coupled to a first set of conductive vias 108 that are coupled to the first gate contact 98. A second end of gate lines 100 opposite the first end may be coupled to a second set of conductive vias 108 that are coupled to the second gate contact 98 (e.g., gate lines 100 may extend from the first set of conductive vias 108 to the second set of conductive vias 108).

Drain node D may also include a set of conductive vias 110 that extend from drain contact 102 downwards through substrate 92 to device 106. Conductive vias 110 may, for example, electrically couple drain contact 102 to device 106 (e.g., conductive vias 110 may extend through one or more openings between gate lines 100 to reach device 106). Gate lines 100 may overlap device 106. Drain contact 102 may overlap device 106. If desired, drain contact 102 may be non-overlapping with respect to gate lines 110 (see, e.g., the top view of FIG. 5).

Source node S (e.g., source lines 96 and/or source contacts 94 of FIG. 5) may be formed from a set of one or more metallization layers MB in substrate 92. If desired, source node S may also include traces in one or more of metallization layers MC (e.g., because the horizontal lines of source node S do not overlap the horizontal lines gate node G). If desired, source node S may include conductive vias coupling different metallization layers MB together and/or to device 106 (e.g., in source lines 96 and/or source contacts 94 of FIG. 5). Implementing source contacts 94 (FIG. 6) as wide metal tracks and/or across multiple metallization layers MB in substrate 92 may help to minimize the impedance of source node S, which can also help to reduce the IR drop in the ground plane for the transistor.

Metallization layer(s) MB may be vertically interposed between metallization layer(s) MC and metallization layer 98 in substrate 92. Metallization layer(s) MC may be vertically interposed between metallization layer(s) MB and device 106. Disposing drain contact 102 on top of transistor unit cell 90 may help to simplify routing when implementing transistor unit cell 90 in amplifier stage 82. The presence of at least some of source node S (e.g., source lines 96 of FIG. 5) between drain contact 102 and gate lines 100 (e.g., in the vertical direction along the Z-axis) may cause source node S to at least partially shield gate lines 100 from drain contact 102. This may help to reduce the extrinsic gate-to-drain capacitance Cgd of transistor unit cell 90, which reduces potential performance degradation due to the Miller effect.

When implemented in this way, transistor unit cell 90 includes a pair of gate contacts 98 on opposing sides of drain contact 102, rather than a single gate contact 98 at a single side of drain contact 102. This may serve to reduce the effective gate resistance of transistor unit cell by a factor of four. If desired, the gate poly and metallization layers (e.g., M1 and M2 layers) may be connected together (e.g., forming gate lines 100), travelling all the way to both ends of the layout and connected to the top metallization layer of substrate 92 (e.g., to the first and second gate terminals 98 in metallization layer MA). This double-sided gate connection may, for example, reduce total gate resistance for transistor unit cell 90 by about 40% relative to implementations where the unit cell includes only a single gate contact/connection.

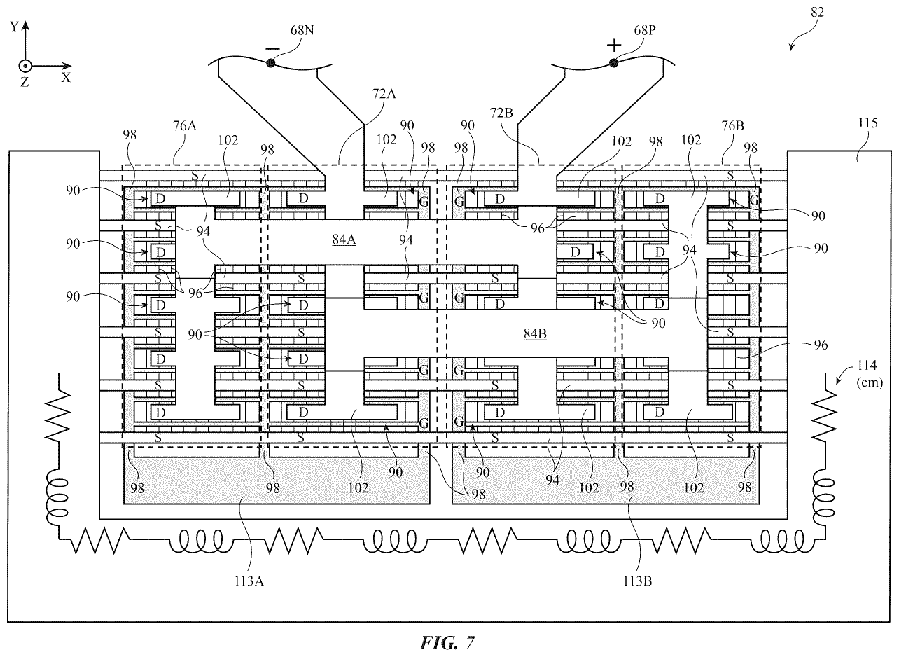

Transistor unit cells such as transistor unit cell 90 of FIGS. 4 and 5 may be used to form some or all of the transistors in amplifier stage 82 of FIG. 4. FIG. 7 is a top (layout) view of amplifier stage 82 in an implementation where each of the transistors 76A, 72A, 72B, and 76B in amplifier stage 82 include a respective set (column) of five transistor unit cells 90. This is illustrative and non-limiting. In general, each transistor may include any desired number of one or more transistor unit cells 90 that are coupled together to perform the operations of the corresponding transistor.

As shown in FIG. 7, the capacitance neutralization transistor 76A of amplifier stage 82 may include a first set (column) of five transistor unit cells 90. The first and second gate contacts 98 of each transistor unit cell 90 in capacitance neutralization transistor 76A may be coupled together by the gate lines 100 in those transistor unit cells 90 (e.g., collectively and electrically forming the gate node/terminal of capacitance neutralization transistor 76A). The first and second gate contacts 98 in each of the transistor unit cells 90 of capacitance neutralization transistor 76A may all be coupled to a shared node 113A, which may be coupled to signal line 80A of FIG. 4. Because each transistor unit cell 90 has two opposing gate contacts 98, voltage applied at shared node 113A (e.g., from input voltage VIN of FIG. 3) is concurrently applied to both gate contacts 98 of each transistor unit cell 90 in capacitance neutralization transistor 76A, which reduces the effective gate resistance of capacitance neutralization transistor 76A relative to implementations where each transistor unit cell 90 includes only a single gate contact 98 at one side of drain contact 102.

The drain contacts 102 of each transistor unit cell 90 of capacitance neutralization transistor 76A may be coupled together (e.g., collectively and electrically forming the drain node/terminal of capacitance neutralization transistor 76A). Each transistor unit cell 90 in capacitance neutralization transistor 76A may include first and second source contacts 94 extending parallel to the gate lines 100 in that transistor unit cell. The source contacts 94 and the source lines 96 in each transistor unit cell 90 of capacitance neutralization transistor 76A may be electrically coupled together (e.g., collectively and electrically forming the source node/terminal of capacitance neutralization transistor 76A). For example, the first and second source contacts 94 in each transistor unit cell 90 of capacitance neutralization transistor 76A may each be coupled to a large resistor (e.g., resistor 78A of FIG. 4). In this implementation, different metallization layers MB (FIG. 6) can be used to implement the source contacts of the capacitance neutralization transistors and the power transistors. For example, the metallization layers MB in capacitance neutralization transistors 76A and 76B may include only a single lower metallization layer, whereas the metallization layers MB in power transistors 72A and 72B may include additional layers in parallel for reducing parasitic resistance and inductance. If desired, peripheral conductor 115 (e.g., a conductor held at reference voltage 64 of FIG. 4) may laterally surround some or all of the sides of amplifier stage 82.

Similarly, the capacitance neutralization transistor 76B of amplifier stage 82 may include a second set (column) of five transistor unit cells 90. The first and second gate contacts 98 of each transistor unit cell 90 of capacitance neutralization transistor 76B may be coupled together by the gate lines 100 in those transistor unit cells 90 (e.g., collectively and electrically forming the gate node/terminal of capacitance neutralization transistor 76B). The first and second gate contacts 98 in each of the transistor unit cells 90 of capacitance neutralization transistor 76B may all be coupled to a shared node 113B, which may be coupled to signal line 80B of FIG. 4. Because each transistor unit cell 90 has two opposing gate contacts 98, voltage applied at shared node 113B (e.g., from input voltage VIN of FIG. 3) is concurrently applied to both gate contacts 98 of each transistor unit cell 90 in capacitance neutralization transistor 76B, which reduces the effective gate resistance of capacitance neutralization transistor 76B relative to implementations where each transistor unit cell 90 includes only a single gate contact 98 at one side of drain contact 102.

The drain contacts 102 of each transistor unit cell 90 of capacitance neutralization transistor 76B may be coupled together (e.g., collectively and electrically forming the drain node/terminal of capacitance neutralization transistor 76B). Each transistor unit cell 90 in capacitance neutralization transistor 76B may include first and second source contacts 94 extending parallel to the gate lines 100 in that transistor unit cell. The source contacts 94 and the source lines 96 in each transistor unit cell 90 of capacitance neutralization transistor 76B may be electrically coupled together (e.g., collectively and electrically forming the source node/terminal of capacitance neutralization transistor 76B). For example, the first and second source contacts 94 in each transistor unit cell 90 of capacitance neutralization transistor 76B may each be coupled to a large resistor (e.g., resistor 78B of FIG. 4).

The power transistor 72A of amplifier stage 82 may include a third set (column) of five transistor unit cells 90. The first and second gate contacts 98 of each transistor unit cell 90 of power transistor 72A may be coupled together by the gate lines 100 in those transistor unit cells 90 (e.g., collectively and electrically forming the gate node/terminal of power transistor 72A). The first and second gate contacts 98 in each of the transistor unit cells 90 of power transistor 72A may all be coupled to shared node 113A (e.g., electrically coupling the gate of power transistor 72A to the gate of capacitance neutralization transistor 76A). Because each transistor unit cell 90 has two opposing gate contacts 98, voltage applied at shared node 113A (e.g., from input voltage VIN of FIG. 3) is concurrently applied to both gate contacts 98 of each transistor unit cell 90 in power transistor 72A (as well as capacitance neutralization transistor 76A), which reduces the effective gate resistance of power transistor 72A relative to implementations where each transistor unit cell 90 includes only a single gate contact 98 at one side of drain contact 102.

The drain contacts 102 of each transistor unit cell 90 of power transistor 72A may be coupled together (e.g., collectively and electrically forming the drain node/terminal of power transistor 72A). Each transistor unit cell 90 in power transistor 72A may include first and second source contacts 94 extending parallel to the gate lines 100 in that transistor unit cell. The source contacts 94 and the source lines 96 in each transistor unit cell 90 of power transistor 72A may be electrically coupled together (e.g., collectively and electrically forming the source node/terminal of power transistor 72A).

The drain of power transistor 72A (e.g., including drain terminals 102 from each of the transistor unit cells 90 in power transistor 72A) may be coupled to the drain of capacitance neutralization transistor 76B (e.g., including drain terminals 102 from each of the transistor unit cells 90 in capacitance neutralization transistor 76B) by conductive line 84B. Conductive line 84B may, for example, extend from a first end coupled to the drain of power transistor 72A to an opposing second end coupled to the drain of capacitance neutralization transistor 76B (e.g., at node 70B of FIG. 4). Conductive line 84B may, for example, be formed from a conductive trace in an additional metallization layer of the substrate (e.g., overlapping or underlying the metallization layer forming drain contacts 102 and gate contacts 98).

The power transistor 72B of amplifier stage 82 may include a fourth set (column) of five transistor unit cells 90. The first and second gate contacts 98 of each transistor unit cell 90 of power transistor 72B may be coupled together by the gate lines 100 in those transistor unit cells 90 (e.g., collectively and electrically forming the gate node/terminal of power transistor 72B). The first and second gate contacts 98 in each of the transistor unit cells 90 of power transistor 72B may all be coupled to shared node 113B (e.g., electrically coupling the gate of power transistor 72B to the gate of capacitance neutralization transistor 76B). Because each transistor unit cell 90 has two opposing gate contacts 98, voltage applied at shared node 113B (e.g., from input voltage VIN of FIG. 3) is concurrently applied to both gate contacts 98 of each transistor unit cell 90 in power transistor 72B (as well as capacitance neutralization transistor 76B), which reduces the effective gate resistance of power transistor 72B relative to implementations where each transistor unit cell 90 includes only a single gate contact 98 at one side of drain contact 102.

The drain contacts 102 of each transistor unit cell 90 of power transistor 72B may be coupled together (e.g., collectively and electrically forming the drain node/terminal of power transistor 72B). Each transistor unit cell 90 in power transistor 72B may include first and second source contacts 94 extending parallel to the gate lines 100 in that transistor unit cell. The source contacts 94 and the source lines 96 in each transistor unit cell 90 of power transistor 72B may be electrically coupled together (e.g., collectively and electrically forming the source node/terminal of power transistor 72B). Power transistors 72A and 72B may share a common source potential (e.g., reference potential 64 in FIG. 4 may be coupled to the source contacts S of both power transistors 72A and 72B) whereas capacitance neutralization transistors 76A and 76B are each provided with their own source potentials by connecting to respective large resistors (e.g., resistors 78A and 78B of FIG. 4 respectively). The source contacts S of power transistors 72A and 72B may be connected to peripheral conductor 115 but are not connected to the source contacts S of capacitance neutralization transistors 76A and 76B.

The drain of power transistor 72B (e.g., including drain terminals 102 from each of the transistor unit cells 90 in power transistor 72B) may be coupled to the drain of capacitance neutralization transistor 76A (e.g., including drain terminals 102 from each of the transistor unit cells 90 in capacitance neutralization transistor 76A) by conductive line 84A. Conductive line 84A may, for example, extend from a first end coupled to the drain of power transistor 72B to an opposing second end coupled to the drain of capacitance neutralization transistor 76A (e.g., at node 70A of FIG. 4). Conductive line 84A may, for example, be formed from a conductive trace in an additional metallization layer of the substrate (e.g., overlapping or underlying the metallization layer forming drain contacts 102 and gate contacts 98). The drain of power transistor 72A may be coupled to terminal 68N of output matching network 62 (FIG. 4). This also serves to electrically couple the drain of capacitance neutralization transistor 76B to terminal 68N through conductive line 84B. The drain of power transistor 72B may be coupled to terminal 68P of output matching network 62 (FIG. 4). This also serves to electrically couple the drain of capacitance neutralization transistor 76A to terminal 68P through conductive line 84A.

When implemented in this way, power transistors 72A and 72B may be laterally interposed between capacitance neutralization transistors 76A and 76B on substrate 92 (e.g., power transistor 72A may be laterally interposed between power transistor 72B and capacitance neutralization transistor 76A whereas power transistor 72B is laterally interposed between power transistor 72A and capacitance neutralization transistor 76B). This may minimize the routing/interconnect path length between the source nodes of power transistors 72A and 72B while also minimizing area consumption by amplifier stage 82. During signal transmission, the signal travels laterally inside each transistor unit cell 90, which are coupled together in a corresponding column to boost the output power of amplifier stage 82. This arrangement leads to a more compact (e.g., square) layout and reduces the length of the overall interconnects relative to implementations where each transistor unit cell 90 includes only a single gate contact 98 at a single side of its drain contact 102 (e.g., in implementations where each transistor unit cell 90 includes only a single gate contact 98 at a single side of its drain contact 102, the capacitance neutralization transistors need to be laterally interposed between the power transistors, which increases the overall area consumed by the amplifier stage).

In addition, this layout may ease connections to the input and output matching networks because the gate and drain terminals appear at two different ends. The double sided gate connections of each transistor unit cell 90 may substantially reduce parasitic gate resistance (see, e.g., parasitic gate resistances R_{g} of FIG. 4) as described above. This configuration may also allow the source nodes of power transistors 72A and 72B to be directly connected together (e.g., at circuit node 74 of FIG. 5) with minimal interconnect length (see, e.g., the very short length of source contacts 94 extending between power transistors 72A and 72B in FIG. 7). This causes there to be almost no source interconnect parasitics between power transistors 72A and 72B and reference voltage 64 in the differential mode, effectively eliminating parasitic source resistances Rₛ and parasitic source inductances Lₛ of FIG. 4 for the differential mode of the transmitted signal. This leaves only common mode (CM) parasitics along the longer interconnect routing path via peripheral conductor 115, as shown by CM parasitics 114. This effectively means that the associated parasitic resistance and inductance of the system do not degenerate the amplifier stage in the differential mode. The parasitic resistance and inductance in the common mode may help with stability of the amplifier stage, as it reduces common mode gain. On the other hand, in implementations where each transistor unit cell 90 includes only a single gate contact 98 on a single side of drain contact 102, the amplifier stage consumes greater area on substrate 92, suffers from higher gate resistance due to one-sided gate connections (e.g., increasing gate resistance), and exhibits higher differential mode parasitic source resistances and inductances, which can substantially degrade power gain and radio-frequency performance.

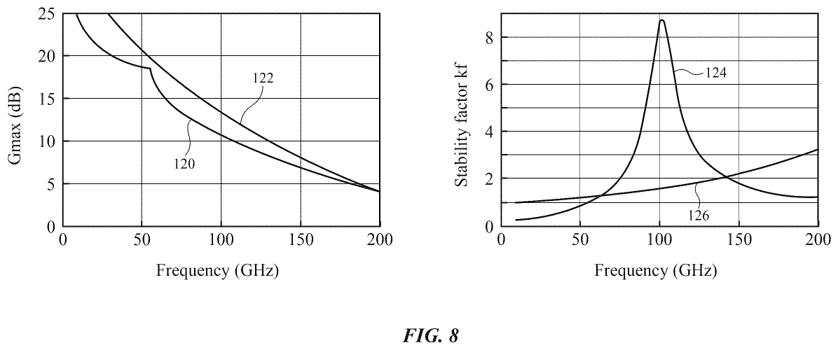

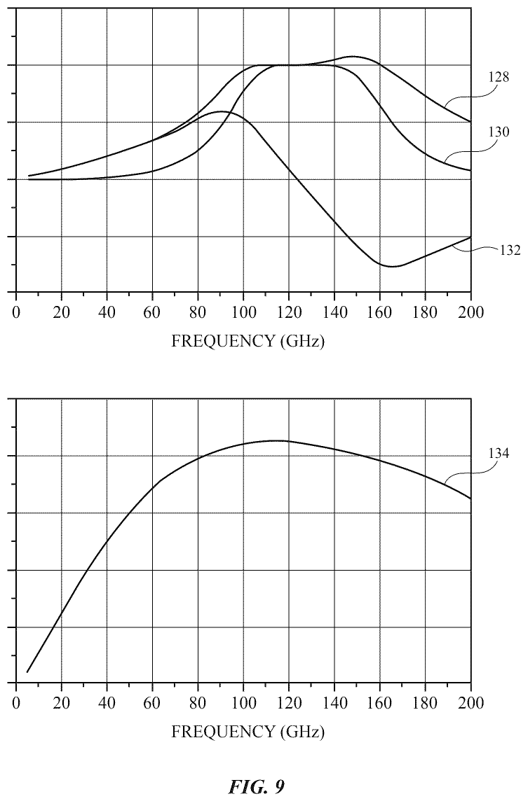

FIG. 8 is a plot illustrating how the implementation of FIGS. 4-7 may improve performance of amplifier 50 relative to implementations where each transistor unit cell 90 includes only a single gate contact 98 on a single side of drain contact 102. Curve 120 plots the maximum gain (Gmax) and curve 124 plots the stability factor kf of the amplifier in implementations where each transistor unit cell 90 includes only a single gate contact 98 on a single side of drain contact 102, as a function of frequency. Curve 122 plots the Gmax and curve 126 plots the kf of the amplifier in the implementation of FIGS. 4-7. As shown by curves 120-126, the implementation of FIGS. 4-7 may serve to increase Gmax (e.g., by as much as 2.4 dB) and may serve to provide a wider bandwidth of stable operation (e.g., a wider frequency range exceeding kf=1) than in implementations where each transistor unit cell 90 includes only a single gate contact 98 on a single side of drain contact 102. In sum, the implementation of FIGS. 4-7 is much less influenced by layout-related parasitics and long interconnect routing relative to implementations where each transistor unit cell 90 includes only a single gate contact 98 on a single side of drain contact 102.

FIG. 9 plots the performance of amplifier 50 (e.g., a D-band amplifier) in an example where output matching network 62 (FIG. 4) includes a coupled-line-based distributed balun. Curve 128 plots the impedance magnitude at terminal 68N, curve 130 plots the real component of the impedance at terminal 68N, and curve 132 plots the imaginary component of the impedance at terminal 68N. The magnitude and impedance components at terminal 68P may follow similar characteristics. Curve 134 plots the passive efficiency (PE) of the amplifier. As shown by curves 128-134, implementing amplifier 50 using the implementation of FIGS. 4-7 may configure the amplifier to exhibit a broadband optimum load impedance while also maintaining a very high passive efficiency (e.g., greater than 84% or higher) over a relatively wide bandwidth (e.g., including D-band frequencies). The examples of FIGS. 8 and 9 are illustrative and non-limiting. In practice, curves 120-134 may have other shapes.

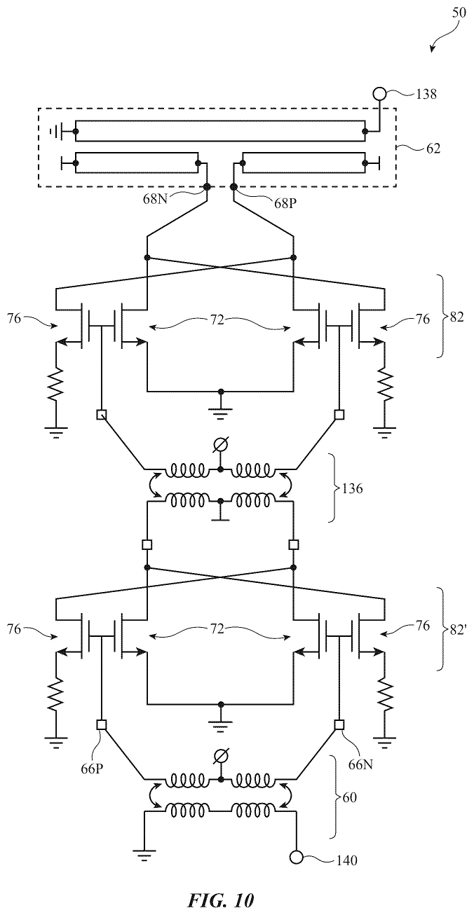

FIG. 10 illustrates another example in which amplifier 50 is a multi-stage amplifier that includes both a first amplifier stage 82 and a second amplifier stage 82′ coupled between input matching network 60 and output matching network 62. As shown in FIG. 10, amplifier stage 82′ may be coupled between input matching network 60 and an inter-stage matching network 136. Amplifier stage 82 may be coupled between interstage matching network 136 and output matching network 62. Each matching network may include a respective transformer if desired. If desired, the input matching network and the output matching network may include baluns. The output matching network 62 in the example of FIG. 10 includes a coupled-line-based distributed balun. This is illustrative and non-limiting.

Input matching network 60 may receive a radio-frequency signal at input terminal 140 (e.g., as a single-ended signal) and may pass the radio-frequency signal onto terminals 66P and 66N (e.g., as a differential signal). Amplifier stage 82′ may be a driver stage that drives the signal onto amplifier stage 82 via interstage matching network 136. Amplifier stage 82 may be a PA stage that amplifies the signal and drives the signal onto output matching network 62. Output matching network 62 may output the signal (e.g., as radio-frequency signal RFSIG of FIG. 3) via output terminal 138 (e.g., as a single-ended signal). Amplifier stage 82 and amplifier stage 82′ may each include a pair of power transistors 72 and a pair of capacitance neutralization transistors 76. Some or all of the transistors in amplifier stage 82 and amplifier stage 82′ may each be implemented using a respective set of one or more transistor unit cells 90 of FIGS. 5 and 6. The transistors of amplifier stage 82 and/or the transistors of amplifier stage 82′ may be laid out as shown in FIG. 7.

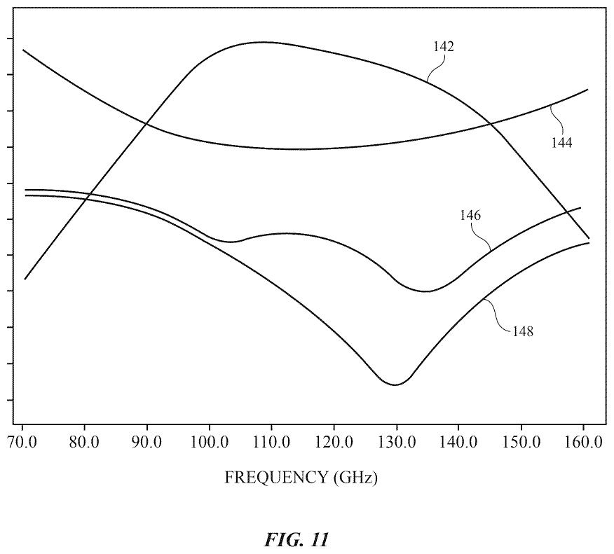

FIG. 11 is a plot of scattering parameters (S-parameters) as a function of frequency for the two-stage amplifier 50 of FIG. 10. As shown in FIG. 11, curve 142 plots an S21 scattering parameter, curve 146 plots an S22 scattering parameter, curve 148 plots an S11 scattering parameter, and curve 144 plots a noise figure of amplifier 50. As shown by curves 142-148, amplifier 50 may exhibit a relatively high peak S21 (characterizing forward signal transfer) such as 19.5 dB at 107 GHz (e.g., with a 3 dB—S21 bandwidth of 98.5-125 GHz), a relatively low S22 (characterizing output port signal reflection), a relatively low S11 (characterizing input port signal reflection), and a sufficiently low noise figure across a relatively wide frequency range that includes the D-band (e.g., as low as 5-5.3 dB from around 116 GHz to around 123 GHz). The input matching network may, for example, configure S11 to be better than −10 dB from around 103 GHz to around 152 GHz.

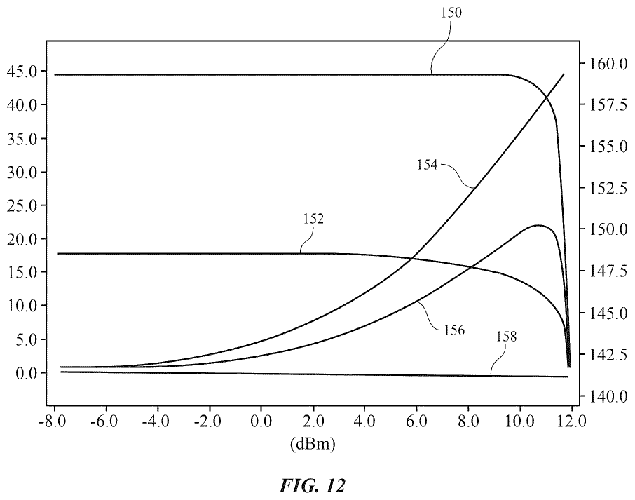

FIG. 12 is a plot showing other performance characteristics of the two-stage amplifier 50 of FIG. 10 in a continuous wave (CW) transmission implementation (e.g., at 120 GHz). Curve 150 of FIG. 12 plots output phase, curve 152 plots gain, curve 154 plots DE of the final amplifier stage, curve 156 plots power-added efficiency (PAE), and curve 158 plots Pdc for the amplifier. At 120 GHz, the amplifier may achieve, for example, an 18 dB power gain and 10.4 dBm saturation power with a very high peak PAE of 22%.

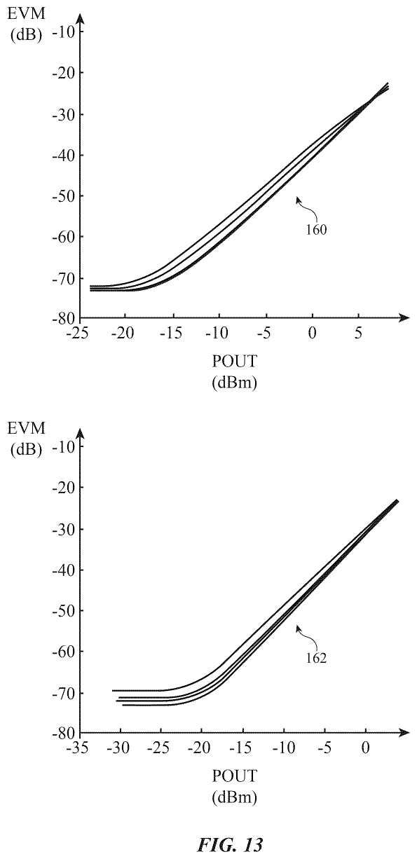

Implementing amplifier 50 in this way may also configure the amplifier to exhibit robust performance across operating frequency and process corners. FIG. 13 plots the error vector magnitude (EVM) of amplifier 50 as a function of output power level POUT under different conditions. Curves 160 of FIG. 13 plot the EVM of amplifier 50 across different frequency, process corner, and temperature variations while transmitting a QPSK signal. Curves 162 of FIG. 13 plot the EVM of amplifier 50 across different frequency, process corner, and temperature variations while transmitting a 64 QAM signal. As shown by curves 160-162, the EVM of amplifier 50 remains relatively low and consistent across modulation schemes and frequency, process corner, and temperature variations. The examples of FIGS. 11-13 are illustrative and, in practice, curves 142-162 may have other shapes.

Implementing amplifier 50 using the transistor unit cells 90 and layout of FIGS. 5-7 may allow amplifier 50 to exhibit similar performance to a three-stage amplifier while only including two amplifier stages 82 and 82′. For example, amplifier 50 may exhibit similar gain using only two amplifier stages as a 3-stage finFET amplifier that includes transistor unit cells with only a single gate contact at a single side of the drain contact, and may exhibit a higher peak PAE (e.g., 22%) relative to amplifiers that includes transistor unit cells with only a single gate contact at a single side of the drain contact (e.g., 12.8%). Implementing amplifier 50 using only two stages may also reduce the area, power consumption and cost of the amplifier relative to implementations with three or more stages.

The methods and operations described above in connection with FIGS. 1-13 may be performed by the components of device 10 using software, firmware, and/or hardware (e.g., dedicated circuitry or hardware). Software code for performing these operations may be stored on non-transitory computer readable storage media (e.g., tangible computer readable storage media) stored on one or more of the components of device 10 (e.g., storage circuitry 16 and/or wireless communications circuitry 24 of FIG. 1). The software code may sometimes be referred to as software, data, instructions, program instructions, or code. The non-transitory computer readable storage media may include drives, non-volatile memory such as non-volatile random-access memory (NVRAM), removable flash drives or other removable media, other types of random-access memory, etc. Software stored on the non-transitory computer readable storage media may be executed by processing circuitry on one or more of the components of device 10 (e.g., processing circuitry in wireless circuitry 24, processing circuitry 18 of FIG. 1, etc.). The processing circuitry may include microprocessors, application processors, digital signal processors, central processing units (CPUs), application-specific integrated circuits with processing circuitry, or other processing circuitry.

As used herein, the term “concurrent” means at least partially overlapping in time. In other words, first and second events are referred to herein as being “concurrent” with each other if at least some of the first event occurs at the same time as at least some of the second event (e.g., if at least some of the first event occurs during, while, or when at least some of the second event occurs). First and second events can be concurrent if the first and second events are simultaneous (e.g., if the entire duration of the first event overlaps the entire duration of the second event in time) but can also be concurrent if the first and second events are non-simultaneous (e.g., if the first event starts before or after the start of the second event, if the first event ends before or after the end of the second event, or if the first and second events are partially non-overlapping in time). As used herein, the term “while” is synonymous with “concurrent.”

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

The foregoing is merely illustrative and various modifications can be made to the described embodiments. The foregoing embodiments may be implemented individually or in any combination.

What is claimed is:

1. A radio-frequency amplifier comprising:
an input matching network;
an output matching network;
a semiconductor substrate; and
an amplifier stage on the semiconductor substrate and coupled between the input matching network and the output matching network, wherein the amplifier stage includes a first transistor, and the first transistor includes
a first drain contact communicatively coupled to the output matching network,
a first gate contact communicatively coupled to the input matching network, and
a second gate contact communicatively coupled to the input matching network, wherein the first drain contact is laterally interposed on the semiconductor substrate between the first gate contact and the second gate contact.

2. The radio-frequency amplifier of claim 1, wherein the first transistor comprises:
a first gate line that couples the first gate contact to the second gate contact; and
a second gate line that couples the first gate contact to the second gate contact parallel to the first gate line.

3. The radio-frequency amplifier of claim 2, wherein the first transistor further comprises:
a first source contact communicatively coupled to a reference voltage;
a second source contact communicatively coupled to the reference voltage; and
a set of source lines that couple the first contact to the second contact.

4. The radio-frequency amplifier of claim 3, wherein:
the first drain contact extends along a first longitudinal axis,
the first source contact extends along a second longitudinal axis parallel to the first longitudinal axis,
the second source contact extends along a third longitudinal axis parallel to the second longitudinal axis,
the set of source lines extend orthogonal to the first, second, and third longitudinal axes,
the first drain contact has first and second edges orthogonal to the first longitudinal axis,
the first drain contact has third and fourth edges extending from the first edge to the second edge parallel to the first longitudinal axis,
the first gate contact faces the first edge of the first drain contact,
the second gate contact faces the second edge of the first drain contact,
the first source contact faces the third edge of the first drain contact, and
the second source contact faces the fourth edge of the first drain contact.

5. The radio-frequency amplifier of claim 1, wherein amplifier stage comprises a common source stage.

6. The radio-frequency amplifier of claim 5, wherein the radio-frequency amplifier comprises a common source amplifier, a cascode amplifier, or an amplifier that implements a stacked topology.

7. The radio-frequency amplifier of claim 1, wherein the first drain contact, the first gate contact, and the second gate contact each comprises a respective portion of a same metallization layer on the semiconductor substrate.

8. The radio-frequency amplifier of claim 1, wherein the first drain contact of the first transistor is coupled to a first input terminal of the output matching network, the amplifier stage comprises a second transistor, and the second transistor includes:
a second drain contact coupled to a second input terminal of the output matching network;
a third gate contact;
a fourth gate contact, wherein the first and second gate contacts of the first transistor are coupled to a first output terminal of the input matching network over a first signal line, the third and fourth gate contacts of the second transistor are coupled to a second output terminal of the input matching network over a second signal line, and the second drain contact is laterally interposed on the semiconductor substrate between third gate contact and the fourth gate contact; and
a source node, wherein the source node is coupled to a reference voltage and a source node of the first transistor.

9. The radio-frequency amplifier of claim 1, wherein the first drain contact of the first transistor is coupled to a first input terminal of the output matching network, the common source amplifier comprises a second transistor, and the second transistor includes:
a second drain contact coupled to a second input terminal of the output matching network;
a third gate contact;
a fourth gate contact, wherein the first and second gate contacts of the first transistor are coupled to a circuit node, the third and fourth gate contacts of the second transistor are coupled to the circuit node, and the circuit node is coupled to an output terminal of the input matching network over a signal path; and
a source node coupled to a reference voltage, wherein a source node of the second transistor is coupled to the reference voltage.

10. The radio-frequency amplifier of claim 9, wherein the second transistor is configured to neutralize a capacitance of the first transistor.

11. The radio-frequency amplifier of claim 1, wherein the first transistor comprises a first power transistor, the first and second gate contacts form part of a first gate node of the first power transistor, the first power transistor has a first source node, the first drain contact is coupled to a first input terminal of the output matching network, and the amplifier stage comprises:
a second power transistor having a second drain contact coupled to a second input terminal of the output matching network, a second gate node, and a second source node, wherein the second source node is coupled to the first source node and a reference voltage;
a first capacitance neutralization transistor having a third source node coupled to the reference voltage, a third drain contact coupled to the second drain contact and the second input terminal of the output matching network, and a third gate node coupled to the first gate node of the first power transistor, wherein the first and third gate nodes are coupled to a first output terminal of the first input matching network; and
a second capacitance neutralization transistor having a fourth source node coupled to the reference voltage, a fourth drain contact coupled to the first drain contact and the first input terminal of the output matching network, and a fourth gate node coupled to the second gate node of the second power transistor, wherein the second and fourth gate nodes are coupled to a second output terminal of the first input matching network.

12. The radio-frequency amplifier of claim 11, wherein the first power transistor is laterally interposed between the first capacitance neutralization transistor and the second power transistor on the semiconductor substrate, and wherein the second power transistor is laterally interposed between the first power transistor and the second capacitance neutralization transistor on the semiconductor substrate.

13. A radio-frequency amplifier comprising:
an input network having first and second terminals;
an output network having third and fourth terminals;
a substrate;
a first transistor on the substrate and having a first gate terminal coupled to the first terminal, a first source-drain terminal coupled to the third terminal, and a second source-drain terminal coupled to a reference voltage;
a second transistor on the substrate and having a second gate terminal coupled to the second terminal, a third source-drain terminal coupled to the fourth terminal, and a fourth source-drain terminal coupled to the second source-drain terminal and the reference voltage;
a third transistor on the substrate and having a third gate terminal coupled to the first terminal and the first gate terminal, a fifth source-drain terminal coupled to the fourth terminal and the third source-drain terminal, and a sixth source-drain terminal coupled to the reference voltage; and
a fourth transistor on the substrate and having a fourth gate terminal coupled to the second terminal and the second gate terminal, a seventh source-drain terminal coupled to the third terminal and the first source-drain terminal, and an eighth source-drain terminal coupled to the reference voltage, wherein
the first and second transistors are laterally interposed on the substrate between the third transistor and the fourth transistor.

14. The radio-frequency amplifier of claim 13, wherein the first transistor is laterally interposed on the substrate between the second and third transistors and wherein the second transistor is laterally interposed on the substrate between the first and fourth transistors.

15. The radio-frequency amplifier of claim 13, wherein the first transistor includes a first set of transistor unit cells, the second transistor includes a second set of transistor unit cells, the third transistor includes a third set of transistor unit cells, and the fourth transistor includes a fourth set of transistor unit cells, the first and second sets of transistor unit cells being laterally interposed on the substrate between the third and fourth sets of transistor unit cells.

16. The radio-frequency amplifier of 15, wherein each transistor unit cell in the first and second sets of unit cells comprises:
an elongated drain contact having first and second edges extending parallel to a longitudinal axis of the elongated drain contact and having third and fourth edges extending from the first edge to the second edge;
a first elongated source contact extending parallel to the elongated drain contact and facing the first edge of the elongated drain contact;
a second elongated source contact extending parallel to the elongated drain contact and facing the second edge of the elongated drain contact;
a first gate contact facing the third edge of the elongated drain contact;
a second gate contact facing the third edge of the elongated drain contact;
a plurality of gate lines that couple the first gate contact to the second gate contact; and
a plurality of source lines that couple the first elongated source contact to the second elongated source contact.

17. The radio-frequency amplifier of claim 16, wherein the plurality of source lines is vertically interposed between the plurality of gate lines and the elongated drain contact.

18. The radio-frequency amplifier of claim 16, wherein the elongated drain contact, the first gate contact, and the second gate contact are formed in a same metallization layer of the substrate.

19. A common source amplifier comprising:
a first set of transistor cells that collectively share a first gate node, a first source node coupled to a reference voltage, and a first drain node, wherein the transistor cells in the first set include
a first drain contact of the first drain node that extends along a longitudinal axis,
a first source contact of the first source node that extends parallel to the longitudinal axis at a first side of the first drain contact,
a second source contact of the first source node that extends parallel to the longitudinal axis at a second side of the first drain contact opposite the first side,
a first gate contact of the first gate node that extends orthogonal to the longitudinal axis at a third side of the first drain contact,
a second gate contact of the first gate node that extends orthogonal to the longitudinal axis at a fourth side of the first drain contact opposite the third side,
a first plurality of gate lines of the first gate node that extend parallel to the longitudinal axis and that couple the first gate contact to the second gate contact, and
a first plurality of source lines of the first source node that extend orthogonal to the longitudinal axis and that couple the first source contact to the second source contact.

20. The common source amplifier of claim 19 further comprising a second set of transistor cells that collectively share a second gate node, a second source node coupled to the first source node and the reference voltage, and a second drain node, wherein the transistor cells in the second set include:
a second drain contact of the second drain node that extends parallel to the longitudinal axis;
a third source contact of the second source node that extends parallel to the longitudinal axis at a first side of the second drain contact and that is coupled to the first source contact of the first set of transistor cells;
a fourth source contact of the second source node that extends parallel to the longitudinal axis at a second side of the second drain contact opposite the first side of the second drain contact and that is coupled to the second source contact of the first set of transistor cells;
a third gate contact of the second gate node that extends orthogonal to the longitudinal axis at a third side of the second drain contact;
a fourth gate contact of the second gate node that extends orthogonal to the longitudinal axis at a fourth side of the second drain contact opposite the third side of the second drain contact;
a second plurality of gate lines of the second gate node that extend parallel to the longitudinal axis and that couple the third gate contact to the fourth gate contact; and
a second plurality of source lines of the second source node that extend orthogonal to the longitudinal axis and that couple the third source contact to the fourth source contact.
